(19) United States
(12) Patent Application Publication
(10) Pub. No.: US 2007/0007641 A1
(43) Pub. Date: Jan. 11, 2007

(54) Chip-embedded interposer structure and fabrication method thereof, wafer level stack structure and resultant package structure

(76) Inventors: Kang-Wook Lee, Gyeonggi-do (KR); Gu-Sung Kim, Gyeonggi-do (KR); Yong-Chai Kwon, Gyeonggi-do (KR); Keum-Hee Ma, Gyeongsangbuk-do (KR); Seong-Il Han, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/348,670

(22) Filed: Feb. 6, 2006

(30) Foreign Application Priority Data
Jul. 8, 2005 (KR) 2005-61573

(51) Int. Cl. H01L 23/52

(52) U.S. Cl. 257/691

(57) ABSTRACT

A method for fabricating a chip-embedded interposer may comprise forming at least one cavity on a silicon substrate, forming a plurality of through vias penetrating the silicon substrate, providing an integrated circuit chip having a plurality of I/O pads, and forming rerouting conductors connected to the I/O pads and the through vias. A stack structure having different kinds of chips may be incorporated at wafer level using the described interposer.

### CROSS REFERENCE TO RELATED APPLICATIONS

This U.S. non-provisional application claims benefit of priority under 35 U.S.C. § 119 of Korean Patent Application No. 2005-61573, filed on Jul. 8, 2005, the entire contents of which are incorporated herein by reference.

### BACKGROUND OF THE INVENTION

1. Field of the Invention

The present invention relates to a semiconductor packaging structure and technique and, more particularly, to a structure and technique for stacking different kinds of integrated circuit chips regardless of chip size.

2. Description of the Related Art

With the advent of a digital network information age, electronic products have been developing rapidly. For example, multimedia products, digital electrical household appliance products and personal digital products are developing rapidly and will likely continue to do so. Under such rapid development, the electronic industry must manufacture reliable, light, compact, high-speed, multifunctional and high-performance electronic products at competitive costs. System-in-package (SIP) structures and techniques have evolved to meet such demands.

The SIP techniques assemble different kinds of chips in a single package to improve electrical performance and reduce size and manufacturing costs. For instance, SIPs including 300 MHz CPU, 1 Gb NAND flash memory, and 256 Mb DRAM in a single package are available. The SIPs provide a variety of multimedia functions to a variety of electronic products, for example game apparatuses, portable phones, digital camcorders, and personal digital assistants, while reducing package size and electromagnetic wave interference phenomena such as may occur with data transmission.

Referring to FIG. 1, a conventional SIP 10 includes a printed circuit board (PCB) 11 and a plurality of chips 12a, 12b, 12c and 12d of different kinds. The chips 12a, 12b and 12c stack on the upper surface of the PCB 11 using adhesives 15 and electrically connect to the PCB 11 using bonding wires 13. The chip 12d, on the lower surface of the PCB 11, electrically connects to the PCB 11 using bumps 14. A molding resin 16 seals the chips 12a, 12b and 12c and the bonding wires 13. An underfill resin 17 seals the chip 12d and the bumps 14. External connection terminals, for example solder balls 18, occupy the lower surface of the PCB 11.

In the SIP 10, the different kinds of chips 12a to 12d connect to the PCB 11 using the bonding wires 13 and the bumps 14. The use of the bonding wires 13 and the bumps 14 may result in relatively long connections, and possibly limitations of system performance and increased package size.

Referring to FIG. 2, an SIP 20 includes a PCB 21 and a plurality of chips 22a, 22b and 22c of different kinds. The chips 22a, 22b and 22c, stacked on the upper surface of the PCB 21, electrically connect to each other using through vias 23 and rerouting lines 24. A substrate 25, having passive devices embedded therein, lies between the chip 22c and the PCB 21 to complement a difference in pad pitch between the chip 22c and the PCB 21. The passive device-embedded substrate 25 has through vias 23 and bumps 26. The substrate 25 connects to the PCB 21 using the bumps 26. Solder balls 27, on the lower surface of the PCB 21, present package connection points.

The SIP 20 has the different kinds of chips 22a to 22c directly interconnected using the through vias 23 and the rerouting lines 24. Such use of the through vias 23 and rerouting lines 24 results in relatively shorter interconnections and improves the system performance while reducing the package size. However, the SIP 20 requires a complicated layout for the through vias 23 and the rerouting lines 24 used in connecting the chips 22a, 22b and 22c having different sizes. If the larger chip 22b is to be stacked on the smaller chip 22c, for example, the SIP 20 may have an impractical or overly complex stack structure.

Because the conventional SIPs 10 and 20 have different kinds of chips and of different sizes, a wafer level stack technique may be difficult to apply to the SIPs 10 and 20. In this aspect, SIPs 10 and 20 represent a lost opportunity to obtain a cost reduction by use of the wafer level stack techniques.

### SUMMARY

An example embodiment of the present invention provides an improved technique for stacking different kinds of chips regardless of chip size.

Another example embodiment of the present invention provides a system-in-package (SIP) having improved system performance, improved chip interconnections, and reduced package size.

Another example embodiment of the present invention provides a wafer-level technique forming a stack structure for different kinds of chips.

According to an example embodiment of the present invention, a chip-embedded interposer structure includes a substrate having an upper surface and a lower surface, at least one cavity formed on the upper surface of the substrate, an integrated circuit chip having a plurality of I/O pads and located at least partially within the cavity, a plurality of through vias penetrating the substrate, and rerouting conductors connected to the I/O pads and to the through vias.

The substrate may be a wafer. The cavities may be formed over the upper surface of the substrate and spaced sufficiently from each other. The through vias may be formed in areas between the cavities.

The depth of the cavity may be smaller than thickness of the substrate. The size of the cavity may be larger than the size of the integrated circuit chip. An adhesive material may be provided between the cavity and the integrated circuit chip. The through vias may extend to the lower surface of the substrate. The through vias may be a metal material filled in through holes of the substrate. An insulating layer may be provided between the through hole and the metal material. A protective layer may be provided between the upper surface of the substrate and the rerouting conductors.

A method for fabricating a chip-embedded interposer may comprise providing a substrate having an upper surface and a lower surface, forming a plurality of through vias on the upper surface of the substrate, forming at least one cavity on the upper surface of the substrate, embedding an integrated circuit chip in the cavity, the chip having a plurality of I/O pads, forming rerouting conductors connected to the I/O pads and the through vias, and thinning the substrate to expose a portion of the through via.

Providing the substrate may include providing a silicon substrate of a wafer shape. Forming the through vias may include forming through holes in the substrate and filling the through holes with a metal material. Forming the through vias may further include forming an insulating layer on inner walls of the through holes.

Forming the cavity may include forming a mask pattern on a portion of the substrate, selectively etching the upper surface of the substrate using the mask pattern, and removing the mask pattern. Embedding the integrated circuit chip may include applying an adhesive material in the cavity and aligning the integrated circuit chip with the cavity to provide the integrated circuit chip in the cavity.

Forming the rerouting conductors may include applying a photoresist on the substrate, patterning the photoresist to connect the I/O pads to the through vias, forming a metal material in the patterned photoresist, and removing the photoresist. Forming the rerouting conductors may further include applying a protective layer on the substrate and patterning the protective layer to expose the I/O pads and the through vias. Thinning of the substrate may include a contact type process for removing a portion of the lower surface of the substrate to reduce the thickness of the substrate and a noncontact type process for removing a portion of the lower surface of the substrate to expose a portion of the through vias.

A wafer level stack structure may comprise a lower interposer and at least one upper interposer. Each interposer may include a substrate having a first surface and a second surface, at least one cavity formed on the first surface of the substrate, an integrated circuit chip having a plurality of I/O pads, a plurality of through vias penetrating the substrate, and rerouting conductors connected to the I/O pads and the through vias. The integrated circuit chip of the upper interposer may have a different size from that of the lower interposer, and the rerouting conductors of the upper interposer may be connected to the through vias of the lower interposer.

The cavity corresponding to the integrated circuit chip of the upper interposer may have a different size in relation to the cavity corresponding to the integrated circuit chip of the lower interposer. The through vias of the lower interposer may extend from the second surface of the substrate. The wafer level stack structure may further comprise a passive device-embedded substrate provided below the lower interposer.

A package structure may comprise a package substrate, a lower interposer and at least one upper interposer. Each interposer may include a substrate having a first surface and a second surface, at least one cavity formed on the first surface of the substrate, an integrated circuit chip having a plurality of I/O pads, a plurality of through vias penetrating the substrate, and rerouting conductors connected to the I/O pads and the through vias. The integrated circuit chip of the upper interposer may have a different size in relation to that of the lower interposer, the rerouting conductors of the upper interposer may be connected to the through vias of the lower interposer, and the rerouting conductors of the lower interposer may be connected to the package substrate.

The package structure may further comprise a passive device-embedded substrate between the package substrate and the lower interposer.

### BRIEF DESCRIPTION OF THE DRAWINGS

Example embodiments of the present invention will be readily understood with reference to the following detailed description thereof provided in conjunction with the accompanying drawings, wherein like reference numerals designate like structural elements.

FIG. 1 (Prior Art) is a cross-sectional view of an example of a conventional system-in-package.

FIG. 2 (Prior Art) is a cross-sectional view of another example of a conventional system-in-package.

FIGS. 3A through 3F are cross-sectional views of a chip-embedded interposer and a related fabrication method in accordance with an example embodiment of the present invention.

FIGS. 4A through 4C are cross-sectional views of a wafer level stack structure including different kinds of chips using the interposer and a related fabrication method in accordance with an example embodiment of the present invention.

FIG. 5 is a cross-sectional view of a package structure using the interposer in accordance with an example embodiment of the present invention.

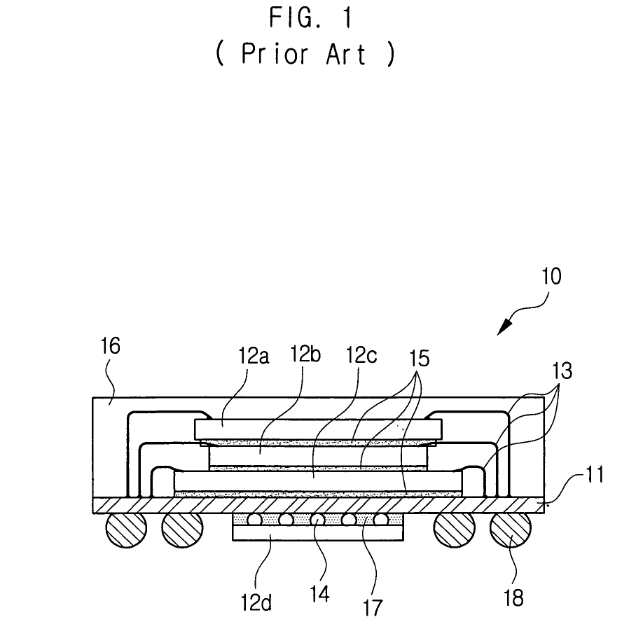

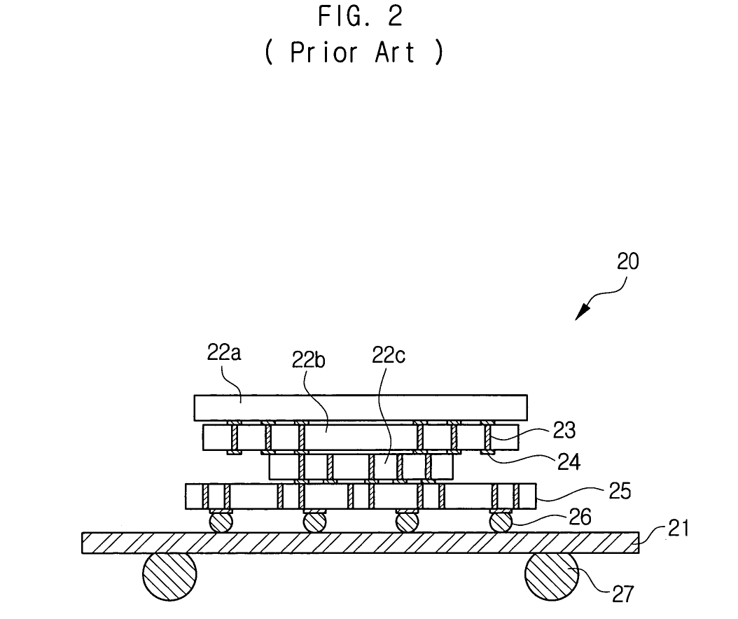

It should be noted that the figures are intended to illustrate the general characteristics of methods and devices of example embodiments of the present invention. These figures are not, however, to scale and may not precisely reflect the characteristics of any given embodiment, and should not be interpreted as defining or limiting the range of values or properties of example embodiments within the scope of this invention. The spatial relationships and relative sizing of the elements illustrated in the various embodiments may have been reduced, expanded or rearranged to improve the clarity of the figure with respect to the corresponding description. The figures, therefore, should not be interpreted as accurately reflecting the relative sizing or positioning of the corresponding structural elements that could be encompassed by an actual device manufactured according to the example embodiments of the invention. For simplicity and clarity of illustration, the dimensions of some of the elements are exaggerated relative to other elements.

### DETAILED DESCRIPTION

Example, non-limiting embodiments of the present invention will now be described more fully hereinafter with reference to the accompanying drawings. This invention may, however, be embodied in many different forms and should not be construed as limited to the particular example embodiments set forth herein. Rather, the disclosed embodiments establish a thorough and complete disclosure, and will convey the invention to those skilled in the art. The principles and feature of the present invention may be employed, therefore, in varied and numerous embodiments without departing from the scope of the invention.

Well-known structures and processes are not described or illustrated in detail to avoid obscuring embodiments of the present invention. Like reference numerals are used for like and corresponding parts of the various drawings.

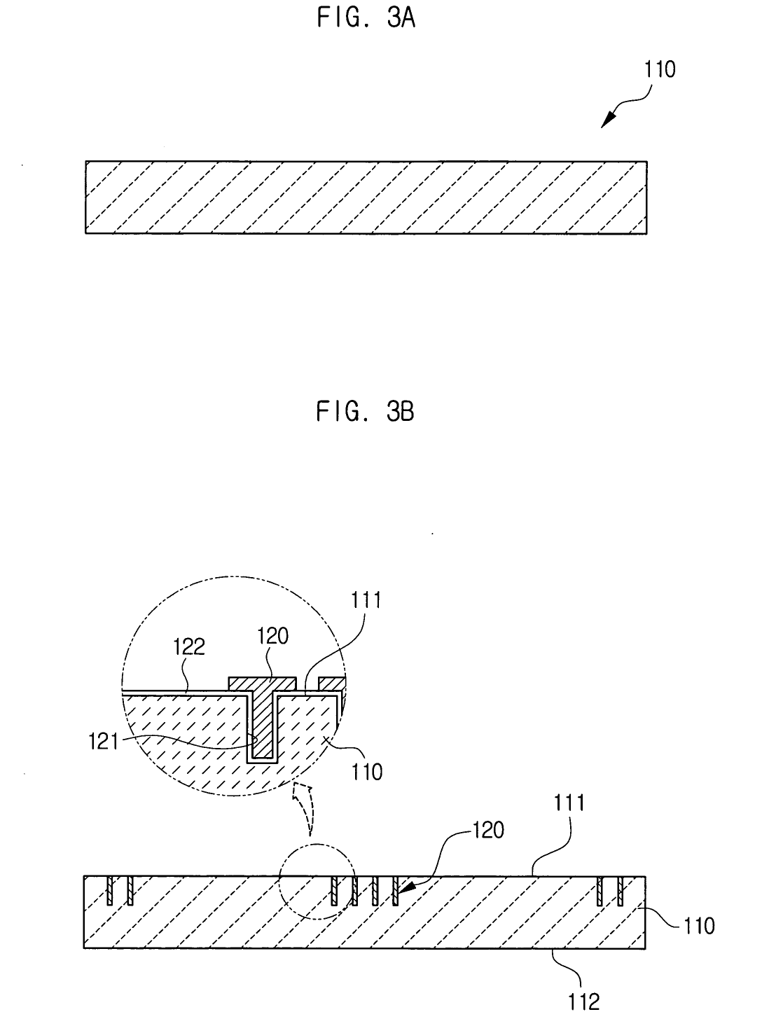

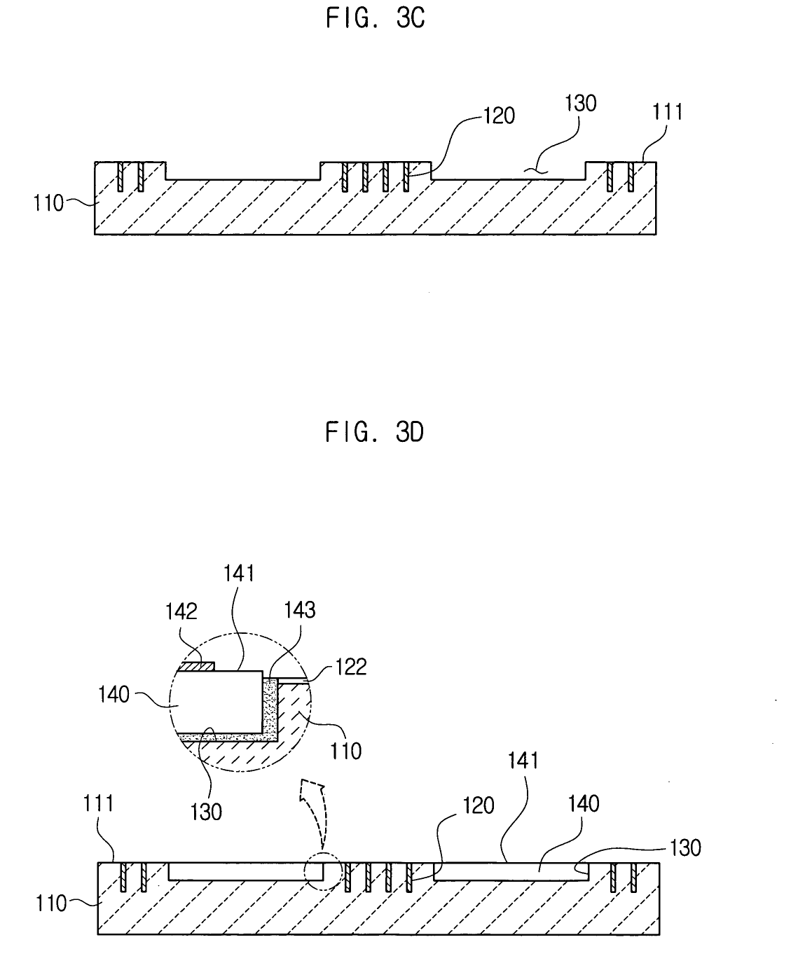

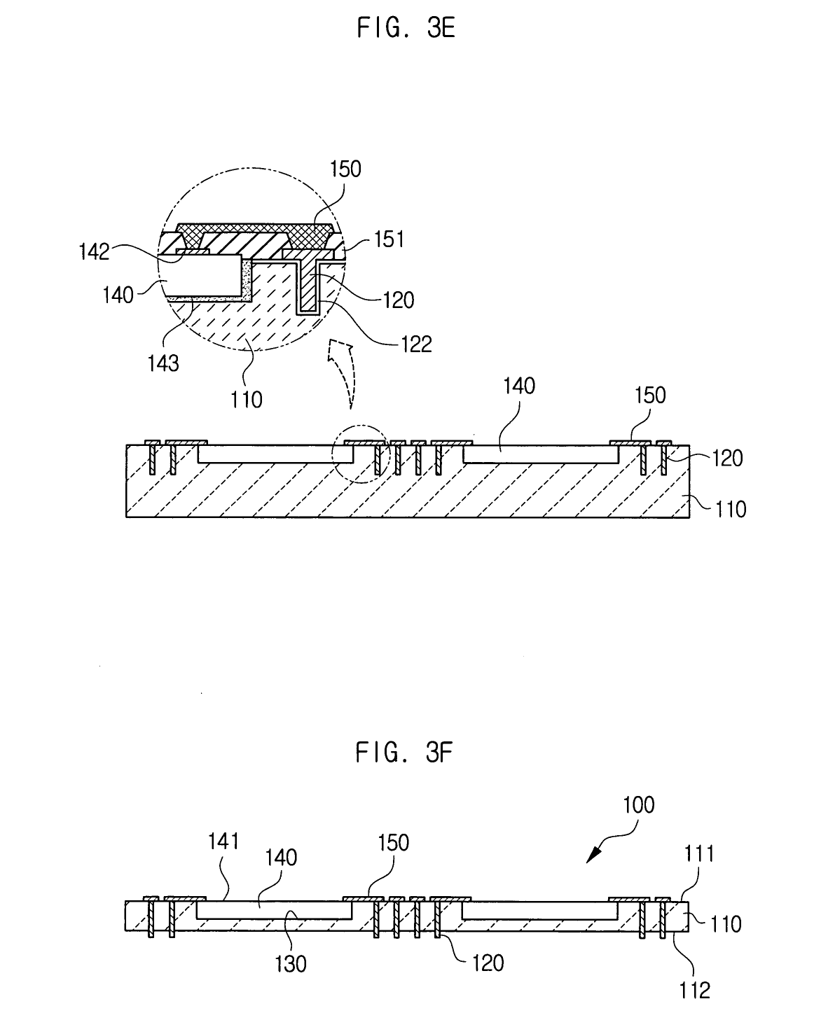

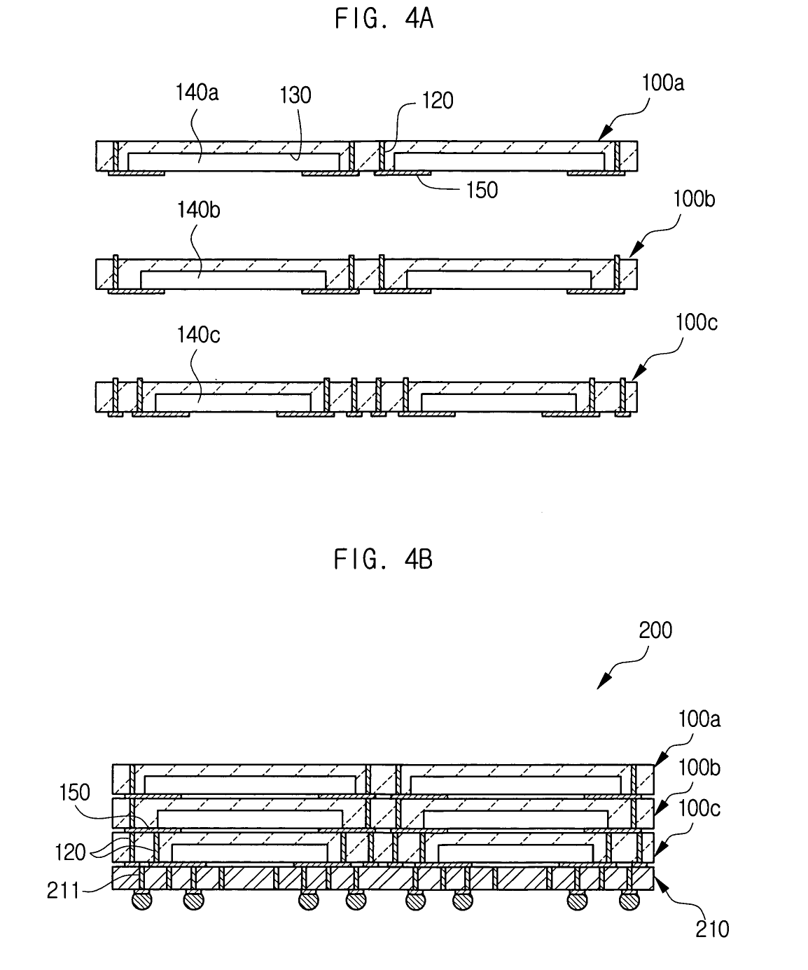

FIGS. 3A through 3F are cross-sectional views of a chip-embedded interposer 100 and a related fabrication method in accordance with an example embodiment of the present invention.

Referring to FIG. 3A, a semiconductor substrate such as silicon substrate 110 may be of a wafer shape presenting an upper surface 111 and a lower surface 112. Although this example embodiment shows the silicon substrate 110 of a wafer shape, the material and shape of the substrate 110 need not be limited in this regard.

The silicon substrate 110, e.g., such as may be used in a typical wafer fabrication process, may be a common plate of silicon initially having no particular additional elements or structures formed therein. Thus, the diameter and thickness of the silicon substrate 110 may be similar to those of a typical wafer. For example, the diameter of the silicon substrate 110 may be 8 inches or 12 inches, and the thickness may be about 700 μm to about 800 μm.

Referring to FIG. 3B, a plurality of through vias (or through holes) 120 may be formed in the silicon substrate 110. The through vias 120 may extend to a predetermined depth from the upper surface 111 of the silicon substrate 110, but at this point need not necessarily extend to the lower surface 112 of the silicon substrate 110. The arrangement of the through vias 120 may be based on the size of the largest chip, in consideration of interconnections on chip stacking as discussed more fully below.

The through holes 121 may be formed in the silicon substrate 110 using a laser process or a dry etch process. An insulating layer 122, for example a silicon nitride, may be formed on the inner walls of the through holes 121. The insulating layers 122 electrically isolate the through vias 120 relative to the silicon substrate 110 and thereby prevent current leakage. The through holes 121 may be filled with metal materials, e.g., copper, gold or tungsten by way of a plating process, to complete the through vias 120.

Referring to FIG. 3C, a plurality of cavities 130 may be formed in the silicon substrate 110. The cavities 130 may be distributed over the upper surface 111 of the silicon substrate 110 and be suitably spaced apart from one another. The size of the cavity 130 may be larger than that of an integrated circuit chip. The cavity forming position may be different from the through via forming position. For example, the cavities 130 may be arranged in areas between the through vias 120.

A mask pattern (not shown) may be formed on the upper surface 111 of the silicon substrate 110 except for the cavity forming position. The mask pattern may be formed of a resist material or a metal layer. The upper surface 111 of the silicon substrate 110 may be selectively etched using the mask pattern. The selective etching process may use a plasma etching method. The mask pattern may be removed.

Referring to FIG. 3D, an integrated circuit chip 140 having a plurality of I/O pads 142 may be embedded in the cavity 130.

An adhesive material 143 may be applied to the cavity 130. The adhesive material 143 may include a liquid, a paste, and a tape type. The integrated circuit chip 140 may be aligned with the cavity 130 and thereby located within the cavity 130. The integrated circuit chip 140 may be connected to the silicon substrate 110 using the adhesive material 143. The height of the integrated circuit chip 140 may be level with the upper surface 111 of the silicon substrate 110, or be higher than the upper surface 111 of the silicon substrate 110 due to the adhesive material 143.

Referring to FIG. 3E, rerouting conductors 150 may be formed to connect the I/O pads 142 to the through vias 120.

Specifically, a protective layer 151 may be formed on the silicon substrate 110 and be patterned to expose the I/O pads 142 of the integrated circuit chip 140 and the through vias 120 of the silicon substrate 110. The protective layer 151 may be formed, for example, of a photosensitive polyimide material. A seed metal layer (not shown) may be formed on the silicon substrate 110 using a sputtering process. A photoresist may be applied on the silicon substrate 110 and be patterned to connect the I/O pads 142 and the through vias 120. A metal material, for example, copper may be formed in the photoresist pattern using an electroplating process. Subsequently, a photoresist removing process and a seed metal layer etching process may be performed, thereby completing the rerouting conductors 150. Although this example embodiment shows the protective layer 151, the protective layer 151 may be a dispensable element in forming the rerouting conductors 150.

Referring to FIG. 3F, the silicon substrate 110 may be thinned. The thinning of the silicon substrate 110 may reduce the thickness of the silicon substrate 110 and expose a portion of the through vias 120. For example, if the thickness of the thinned silicon substrate 110 is about 100 μm, the depth of the cavity 130 may be about 50 μm.

The thinning of the silicon substrate 110 may include a contact type process and a noncontact type process. The contact type process may remove a portion of the lower surface 112 of the silicon substrate 110 to reduce the thickness of the silicon substrate 110. The noncontact type process may remove a further portion of the lower surface 112 of the silicon substrate 110 to expose a portion of the through vias 120. The contact type process may include a mechanical grinding process and a chemical mechanical polishing process. The noncontact type process may include a spin wet etching process and a dry etching process. The manufacture of the interposer 100 having chip embedded therein may thus be completed.

The resultant interposer 100 may comprise a silicon substrate 110 having an upper surface 111 and a lower surface 112, at least one cavity 130 formed on the upper surface 111 of the silicon substrate 110, an integrated circuit chip 140 having a plurality of I/O pads 142, a plurality of through vias 120 penetrating the silicon substrate 110, and rerouting conductors 150 connected to the I/O pads 142 and the through vias 120.

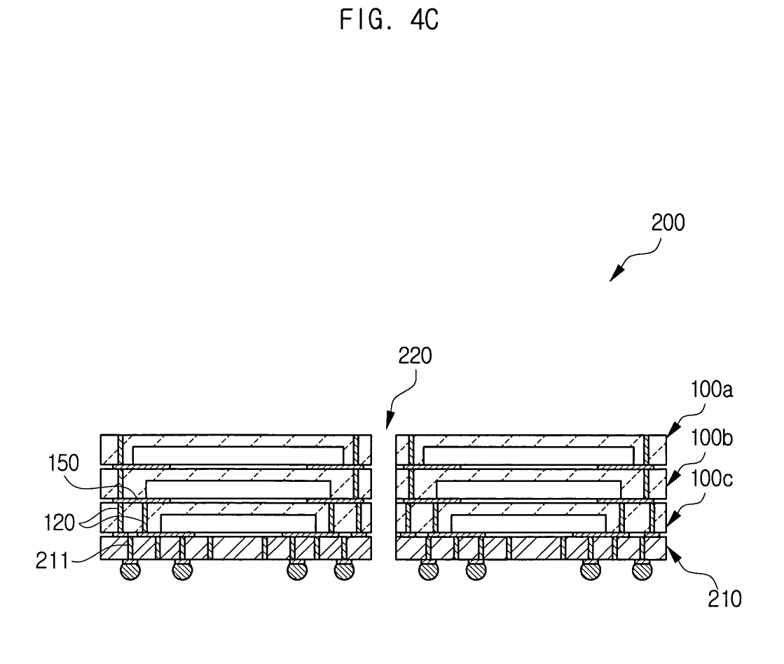

FIGS. 4A through 4C are cross-sectional views of a wafer level stack structure 200 having different kinds of chips using an interposer and a related fabrication method in accordance with an example embodiment of the present invention.

Referring to FIG. 4A, interposers 100a, 100b and 100c, each include chips 140a, 140b and 140c, respectively, embedded therein. The chips 140a, 140b and 140c may be different kinds of chips having different sizes, but intended for interconnection as a SIP. The interposers 100a, 100b and 100c have the same structure and manufacturing method as the interposer 100, and are shown in an inverted configuration relative to that of the earlier illustrations. Accordingly, further description, e.g., that in common with the interposer 100, will be omitted.

The integrated circuit chips 140a, 140b and 140c may have different sizes, and corresponding cavities 130 may have different sizes. The arrangement of the through vias 120 may be designed based on the size of the largest chip 140a, in consideration of interconnections upon chip stacking. Once the size of the cavity 130 and the arrangement of the through vias 120 are set, the arrangement of rerouting conductors 150 may be set accordingly.

Referring to FIG. 4B, the interposers 100a, 100b and 100c may be vertically stacked to form the wafer level stack structure 200. The interposer 100a may be hereinafter referred to as an uppermost interposer, the interposer 100b as an intermediate interposer, and the interposer 100c as a lowest interposer. The interposers 100a, 100b and 100c may be mechanically and electrically connected to each other using, for example, a thermo compression bonding method. For example, the through vias 120 of the lowest interposer 100c may be connected to the rerouting conductors 150 of the intermediate interposer 100b. At this time, the through vias 120 extending from the lower surface of a silicon substrate may allow easier and securer connections of the through vias 120 with the rerouting conductors 150.

To form a system-in-package, the wafer level stack structure 200 may be connected to a package substrate. At this time, a large pitch of connection pads between the lowest interposer 100c and the package substrate may result in poor connection. To solve the pitch issue, the wafer level stack structure 200 may further comprise a substrate 210 having passive devices (not shown) embedded therein. The passive device-embedded substrate 210 may have through vias 211 and bumps 212. In other embodiments of the present invention, the passive device-embedded substrate 210 need not be included in the wafer level stack structure 200.

Referring to FIG. 4C, the resultant wafer level stack structure 200 may be divided into individual stack structures along scribe lines 220. The dicing process may use a cutter or laser in similar manner to a typical wafer sawing process. Thus, multiple package structures, e.g., the package structures 300, may be obtained from one wafer level stack structure 200.

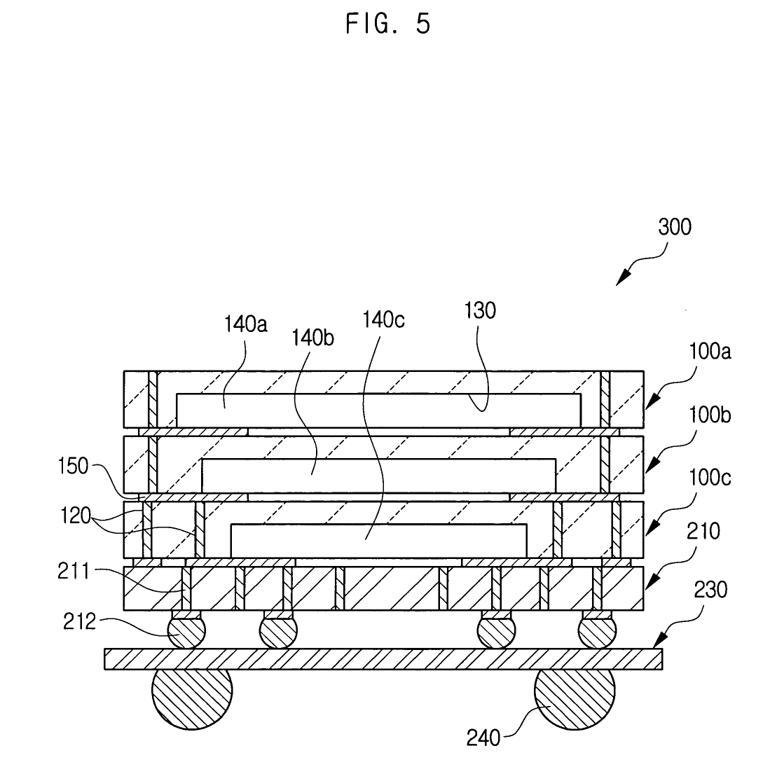

FIG. 5 is a cross-sectional view of a package structure 300 using the herein described interposer technique in accordance with an example embodiment of the present invention.

Referring to FIG. 5, the package 300 being a system-in-package may comprise a package substrate 230, and interposers 100a, 100b and 100c having different kinds of chips 140a, 140b and 140c, respectively. The chips 140a, 140b and 140c may include, for example, DRAM, NAND flash and CPU, circuitry, respectively. Each of the interposers 100a, 100b and 100c may have cavities 130 for receiving the chips 140a, 140b and 140c, through vias 120 formed near the cavities 130, and rerouting conductors 150 connected to the through vias 120. The chips 140a, 140b and 140c may be electrically connected to each other using the through vias 120 and rerouting conductors 150. A substrate 210 having passive devices embedded therein may be provided between the lowest interposer 100c and the package substrate 230. External connection terminals, for example solder balls 240, may be formed on the lower surface of the package substrate 230.

The interconnections using the through vias 120 and the rerouting conductors 150 may allow improved system performance and reduced package size. The through vias 120 need not be formed in the chips 140a, 140b and 140c, but rather in the interposers 100a, 100b and 100c. This may result in a less restrictive layout of the through vias 120 and the rerouting conductors 150, thereby facilitating desired interconnections between chips. The uniform size of the interposers 100a, 100b and 100c may lead to a stable SIP structure.

In accordance with the example embodiments of the present invention, the chip-embedded interposer allows stacking of different kinds of chips regardless of chip size.

The chip-embedded interposer provides interconnections using through vias and rerouting conductors, thereby improving the system performance and reducing the package size.

The chip-embedded interposer having through vias formed therein provides less restrictive layout of the through vias and rerouting conductors, thereby facilitating desired interconnections between chips.

The chip-embedded interposer having a size relatively uniform as compared to other chip-embedded interposers provides a structural stability of a SIP formed thereby.

The chip-embedded interposer of as a wafer form incorporates a stack structure at a wafer level, thereby reducing manufacturing costs.

Although example, non-limiting embodiments of the present invention have been described in detail hereinabove, it should be understood that many variations and/or modifications of the basic inventive concepts herein taught, which may appear to those skilled in the art, will still fall within the spirit and scope of the example embodiments of the present invention as defined in the appended claims.

What is claimed is:

1. A chip-embedded interposer structure comprising:
a substrate having an upper surface and a lower surface;
at least one cavity formed on the upper surface of the substrate;
an integrated circuit chip having a plurality of I/O pads and located at least partially within the at least one cavity;
a plurality of through vias penetrating the substrate; and
rerouting conductors connected to the I/O pads and the through vias.

2. The structure of claim 1, wherein the substrate is a silicon substrate.

3. The structure of claim 1, wherein the substrate is a wafer.

4. The structure of claim 1, wherein the at least one cavity in the upper surface of the substrate is located in spaced relation relative to an adjacent cavity.

5. The structure of claim 4, wherein at least some of the through vias are located intermediate the at least one cavity and the adjacent cavity.

6. The structure of claim 1, wherein a depth of the at least one cavity is less than a thickness of the substrate.

7. The structure of claim 1, wherein a size of the at least one cavity is greater than a size of the integrated circuit chip.

8. The structure of claim 7, wherein an adhesive lies between the at least one cavity and the integrated circuit chip when located therein.

9. The structure of claim 1, wherein the through vias extend to the lower surface of the substrate.

10. The structure of claim 1, wherein at least one of the through vias comprises a metal material filling in a through hole of the substrate.

11. The structure of claim 10, including an insulating layer between the through hole and the metal material.

12. The structure of claim 1, including a protective layer between the upper surface of the substrate and the rerouting conductors.

13. A method for fabricating a chip-embedded interposer, the method comprising:
providing a substrate having an upper surface and a lower surface;
forming a plurality of through vias on the upper surface of the substrate;
forming at least one cavity on the upper surface of the substrate;
embedding an integrated circuit chip in the at least one cavity, the chip having a plurality of I/O pads;
forming rerouting conductors connected to the I/O pads and to the through vias; and
thinning the substrate to expose a portion of the through vias at the lower surface of the substrate.

14. The method of claim 13, wherein providing a substrate includes providing a silicon substrate.

15. The method of claim 13, wherein providing the substrate includes providing a wafer-form substrate.

16. The method of claim 13, wherein forming a plurality of through vias includes forming a corresponding plurality of through holes in the substrate and filling the plurality of through holes with a metal material.

17. The method of claim 16, wherein forming a plurality of through vias further includes forming an insulating layer on inner walls of each of the plurality of through holes.

18. The method of claim 13, wherein forming at least one cavity includes forming a mask pattern on a portion of the substrate, selectively etching the upper surface of the substrate using the mask pattern, and removing the mask pattern.

19. The method of claim 13, wherein embedding an integrated circuit chip includes applying an adhesive material in the cavity and aligning the integrated circuit chip relative to the cavity to locate the integrated circuit chip at least partially within the cavity.

20. The method of claim 13, wherein forming the rerouting conductors includes applying a photoresist on the substrate, patterning the photoresist to connect the I/O pads to the through vias, forming a metal material in the patterned photoresist, and removing the photoresist.

21. The method of claim 20, wherein forming the rerouting conductors further includes applying a protective layer on the substrate and patterning the protective layer to expose the I/O pads and the through vias.

22. The method of claim 13, wherein thinning the substrate includes at least one of a contact type process to remove a portion of the lower surface of the substrate and thereby reduce the thickness of the substrate and a noncontact type process to remove a portion of the lower surface of the substrate and thereby expose a portion of the through vias.

23. A wafer level stack structure comprising:
a lower interposer; and
at least one upper interposer,
each interposer including:
a substrate having a first surface and a second surface;
at least one cavity formed on the first surface of the substrate;
an integrated circuit chip having a plurality of I/O pads;
a plurality of through vias penetrating the substrate; and
rerouting conductors connected to the I/O pads and the through vias,
wherein the integrated circuit chip of the upper interposer has a different size relative to that of the lower interposer, and the rerouting conductors of the upper interposer are connectable to the through vias of the lower interposer.

24. The structure according to claim 23, wherein the substrate is a silicon substrate.

25. The structure of claim 23, wherein the cavity corresponding to the integrated circuit chip of the upper interposer has a different size in relation to the cavity corresponding to the integrated circuit chip of the lower interposer.

26. The structure of claim 23, wherein the through vias of the lower interposer extend to the second surface of the corresponding substrate.

27. The structure of claim 23, further comprising a passive device-embedded substrate provided below the lower interposer.

28. A package structure comprising:
a package substrate;
a lower interposer; and
at least one upper interposer,
each interposer including:
a substrate having a first surface and a second surface;
at least one cavity formed on the first surface of the substrate;
an integrated circuit chip having a plurality of I/O pads and located relative to at least one the cavity;
a plurality of through vias penetrating the substrate; and
rerouting conductors connected to the I/O pads and the through vias,
wherein the integrated circuit chip of the upper interposer has a different size in relation to that of the lower interposer, the rerouting conductors of the upper interposer are connected to the through vias of the lower interposer, and the rerouting conductors of the lower interposer are connected to the package substrate.

29. The structure of claim 28, wherein each substrate comprises a silicon substrate.

30. The structure of claim 28, further comprising a passive device-embedded substrate between the package substrate and the lower interposer.
